(19) United States
(12) Patent Application Publication
(10) Pub. No.: US 2024/0220837 A1
(43) Pub. Date: Jul. 4, 2024

(54) DYNAMICALLY DECOUPLED DRIVEN CONTROLLED-Z GATE

(71) Applicant: ALIBABA GROUP HOLDING LIMITED, George Town, Grand Cayman (KY)

(72) Inventors: Dawei DING, San Diego, CA (US); Feng WU, Hangzhou, Zhejiang (CN); Huihai ZHAO, Beijing (CN)

(21) Appl. No.: 18/550,756

(22) PCT Filed: Apr. 13, 2021
(86) PCT No.: PCT/US2021/027092

§ 371 Date: Sep. 15, 2023

(51) Int. Cl. G06N 10/20; G06N 10/40

(52) U.S. Cl. CPC G06N 10/20; G06N 10/40

(57) ABSTRACT

Systems and methods are provided for performing a dynamic decoupled controlled-Z gate operation. A superconducting circuit of an exemplary system can include a first qubit and a second qubit transversely coupled to the first qubit, lire system can apply an external magnetic flux to the second qubit to bring a frequency of the second qubit into resonance with a frequency of the first qubit. The system can apply a continuous alternating drive with continuous phase to the second qubit, a duration and a magnitude of the continuous alternating drive configured to synchronize agate time of the dynamic decoupled controlled-Z gate operation to an integer number of Rabi oscillation periods. The system can read out a state of the quantum computing system, after providing the continuous alternating drive.

### TECHNICAL FIELD

The present disclosure generally relates to quantum computing, and more particularly, to operation of a dynamically driven controlled-Z gate.

### BACKGROUND

Quantum computations are performed on quantum bits, or qubits. Such computations can be performed by quantum gates, which are analogous to the logic gates of digital computations. One such quantum gate is the Z gate, which can perform a phase shift on a qubit when the qubit is the excited state, rotating the phase of the qubit by π radians. When the qubit is not in the excited state, the Z gate can have no effect. The controlled-Z gate is a two-qubit extension of the Z gate. When the first of the two qubits is in the excited state, then the controlled-Z gate can perform the Z gate operation on the second of the two qubits. When the first of the two qubits is not in the excited state, the state of the second qubit may not be affected.

Quantum computation can be limited by decoherence arising from interactions between qubits and their environment. Dynamically decoupling drives can be used to suppress such decoherence, extending the time for performing quantum operations.

### SUMMARY

The disclosed systems and methods relate to controlled-Z gates configured to use dynamic decoupling (DD) drives synchronized to integer numbers of Rabi oscillations. Such DD drives can support reduced gate times and increased gate fidelity, constituting a technical improvement in quantum computing.

The disclosed embodiments include a quantum computing system for performing a dynamically decoupled controlled-Z gate operation. The system can include a superconducting circuit and at least one computing device. The superconducting circuit can include a first qubit and a second qubit transversely coupled to the first qubit. The at least one computing device can be configured to provide first, second, and third instructions. The first instructions can be provided to a first drive source. The first instructions can cause the first drive source to apply an external magnetic flux to the second qubit to bring a frequency of the second qubit into resonance with a frequency of the first qubit. The second instructions can be applied to a second drive source. The second instructions can cause the second drive source to apply a continuous alternating drive with continuous phase to the second qubit, a duration and a magnitude of the continuous alternating drive configured to synchronize a gate time of the dynamically decoupled controlled-Z gate operation to an integer number of Rabi oscillation periods. The third instructions can be provided after providing the second instructions to the second drive source. The third instructions can be to read out a state of the quantum computing system.

The disclosed embodiments include a method for performing a dynamically decoupled controlled-Z gate operation. The method can include providing, by a first drive source to a second qubit of a superconducting circuit of a quantum computing system, an external magnetic flux to tune a frequency of the second qubit to a frequency of a first qubit, the first qubit being transversely coupled to the second qubit. The method can further include providing, by a second drive source to the second qubit, a continuous alternating drive, a magnitude of the continuous alternating drive corresponding to a peak in a relationship between the magnitude and a fidelity of the dynamically decoupled controlled-Z gate operation. The method can additionally include reading out, after providing the second drive source, a state of the quantum computing system.

The disclosed embodiment can include a non-transitory computer-readable medium comprising instructions that, when processed by a quantum computing system, cause the quantum computing system to perform first operations for implementing a dynamically decoupled controlled-Z gate operation. The first operations can include providing, by a first drive source to a second qubit of a superconducting circuit, an external magnetic flux to tune a frequency of the second qubit to a frequency of a first qubit, the first qubit being transversely coupled to the second qubit. The first operations can further include providing, by a second drive source to the second qubit, a continuous alternating drive. A duration of the continuous alternating drive can be based inversely on a magnitude of the continuous alternating drive and can be within 10% of a quotient of pi divided by the magnitude of the continuous alternating drive. The first operations can include reading out, after providing the second drive source, a state of the quantum computing system.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which comprise a part of this specification, illustrate several embodiments and, together with the description, serve to explain the principles and features of the disclosed embodiments. In the drawings:

FIG. 1A depicts a schematic of an exemplary circuit for implementing a controlled-Z gate, in accordance with disclosed embodiments.

FIG. 1B depicts a table of values for an exemplary instance of the exemplary circuit depicted in FIG. 1A, in accordance with disclosed embodiments.

FIG. 1C depicts a matrix of Hamiltonian coefficients for the exemplary circuit depicted in FIG. 1A, in accordance with disclosed embodiments.

FIG. 1D depicts a matrix representing application of a dynamically decoupling drive to the exemplary circuit depicted in FIG. 1A, in accordance with disclosed embodiments.

FIG. 1E depicts a unitary matrix of a dynamically decoupling drive CZ quantum gate (DDCZ gate) locally equivalent to a controlled-Z gate, in accordance with disclosed embodiments.

FIG. 2A depicts gate fidelity as a function of DD drive amplitude for a conventional DD drive, without including leakage effects.

FIG. 2B depicts gate fidelity as a function of DD drive amplitude, without considering leakage effects and in accordance with disclosed embodiments.

FIG. 3A depicts gate fidelity as a function of DD drive amplitude for a conventional DD drive, including leakage effects.

FIG. 3B depicts gate fidelity as a function of DD drive amplitude including leakage effects, and in accordance with disclosed embodiments.

FIG. 4A depicts state evolution of a controlled-Z gate, in accordance with disclosed embodiments.

FIG. 4B depicts state evolution of a controlled-Z gate for a conventional DD drive when a first DD amplitude is applied.

FIG. 4C depicts state evolution of a controlled-Z gate for a conventional DD drive when a second DD amplitude is applied.

FIG. 5 depicts a flowchart of an exemplary method for operating a controlled-Z gate, in accordance with disclosed embodiments.

### DETAILED DESCRIPTION

Reference will now be made in detail to exemplary embodiments, discussed with regards to the accompanying drawings. In some instances, the same reference numbers will be used throughout the drawings and the following description to refer to the same or like parts. Unless otherwise defined, technical or scientific terms have the meaning commonly understood by one of ordinary skill in the art. The disclosed embodiments are described in sufficient detail to enable those skilled in the art to practice the disclosed embodiments. It is to be understood that other embodiments may be utilized and that changes may be made without departing from the scope of the disclosed embodiments. Thus, the materials, methods, and examples are illustrative only and are not intended to be necessarily limiting.

Quantum computers offer the ability to perform certain tasks (equivalently, solve certain problems) thought to be intractable to classical computers, including any possible future classical computers. To understand the advantage of quantum computers, it is useful to understand how they contrast to classical computers. A classical computer operates according to digital logic. Digital logic refers to a type of logic system that operates on units of information called bits. A bit may have one of two values, usually denoted 0 and 1, and is the smallest unit of information in digital logic. Operations are performed on bits using logic gates, which take one or more bits as input and give one or more bits as output. Typically, a logic gate usually only has one bit as output (though this single bit may be sent as input to multiple other logic gates) and the value of this bit usually depends on the value of at least some of the input bits. In modern-day computers, logic gates are usually composed of transistors and bits are usually represented as the voltage level of wires connecting to the transistors. A simple example of a logic gate is the AND gate, which (in its simplest form) takes two bits as input and gives one bit as output. The output of an AND gate is 1 if the value of both inputs is 1 and is zero otherwise. By connecting the inputs and outputs of various logic gates together in specific ways, a classical computer can implement arbitrarily complex algorithms to accomplish a variety of tasks.

On a surface level, quantum computers operate in a similar way to classical computers. A quantum computer operates according to a system of logic that operates on units of information called qubits (a portmanteau of “quantum” and “bit”). A qubit is the smallest unit of information in quantum computers and the qubit may have any linear combination of two values, usually denoted |0 [symbol] and |1 [symbol] . In other words, the value of a qubit, denoted |ψ [symbol] , could be equal to α|0 [symbol] +β|1 [symbol] for any combination of α and β where α and β are complex numbers and |α|²+[β]²=1. Operations are performed on qubits using quantum logic gates, which take one or more qubits as input and gives one or more qubits as output. Given the low-level nature of most current quantum systems, quantum algorithms are typically expressed in terms of their underlying quantum circuits. In turn, quantum circuits are composed of quantum gates, the fundamental components that directly manipulate qubits.

Controlled-Z gates are quantum gates that act on two qubits. When the first qubit is in the |0 [symbol] state, the controlled-Z gate has no effect on the state of the second qubit. When the first qubit is in the |1 [symbol] state and the second qubit is in the |0 [symbol] state, the controlled-Z gate has no effect on the state of the second qubit. When the first and second qubit are both in the |1 [symbol] state, then the controlled-Z gate reverses the phase of the second qubit.

A controlled-Z gate can be constructed from a two-qubit gate that is locally equivalent to the controlled-Z gate. Such a gate may differ from the controlled-Z gate only in local operations. For example, a DDCZ gate can be locally equivalent to a controlled-Z gate, when performed together with the following single-qubit operations:

Given an M gate with the unitary

$$M = \frac{1}{\sqrt{2}} [ \begin{matrix}1 & 1 \\ {e}^{- i π / 4} & - {e}^{- i π / 4}\end{matrix} ] ,$$

where an Mt gate is the conjugate transpose of an M gate and M⊗M gate is the Kronecker product of two M gates (representing the parallel application of two M gates to two separate qubits).

Given an N gate with the unitary

$$N = [ \begin{matrix}{e}^{i π / 4} & 0 \\ 0 & {e}^{- i π / 4}\end{matrix} ] ,$$

where an N⊗N gate is the Kronecker product of two N gates (representing the parallel application of two N gates to two separate qubits).

Then a controlled-Z gate (CZ) can be constructed by applying two M^{†} gates in parallel, applying the DDCZ gate, applying two M gates in parallel, and then applying two N gates in parallel (to a global factor of e^{iπ/4} that lacks physical relevance): (N⊗N) (M⊗M)DDCZ(M^{†}⊗M^{†})=e^{iπ/4}CZ.

Superconducting quantum circuits can be used to implement qubits and quantum gates. Such qubits can be based on currents (e.g., flux qubits) or charges (e.g., charge qubits), or energy (e.g., phase qubits). Different implementations can have different characteristics, such as sensitivity to external noise, coherence time, or anharmonicity. For example, a transmon qubit, a type of charge qubit including a capacitively shunted Josephson junction, can exhibit a reduced sensitivity to charge noise. As an additional example, fluxonium qubit, a type of flux qubit including a Josephson junction shunted by a capacitor and an inductor (the latter realizable using an array of additional Josephson junctions), can exhibit long coherence times and large anharmonicity.

Providing dynamic decoupling (DD) drives to one or more qubits can improve qubit performance. DD drives can be, or include, microwave drives that are resonant with the one or more qubits. Such DD drives can refocus the time evolution of the qubit, causing noises localized around individual qubits to be effectively averaged out. In this manner, a DD drive can at least partially isolate a qubit from dephasing noise with a correlation time longer than the period of a Rabi oscillation. Accordingly, a DD drive can extend the dephasing times of a qubit, thereby permitting more (or more complicated) quantum computations.

Certain DD drives for controlled-Z gates can use a continuous waveform to isolate a qubit from dephasing noise during gate operation. However, such DD drives includes a π phase shift midway through application of the continuous waveform. This phase shift acts to reduce phase accumulation due to the qubit frequency, as phase accumulating during the first portion of the DD drive is canceled by phase accumulating during the second portion of the DD drive. Furthermore, this approach requires that the magnitude of the difference in Rabi frequencies between DD drives applied to each qubit greatly exceed the interaction term in the two-qubit Hamiltonian:

$$\vert {Ω}_{A} - {Ω}_{B} \vert >> \vert λ \vert \qquad Eq . 1$$

where Ω_{A} and Ω_{B} are the Rabi frequencies for each DD drive and λ is the interaction term in the two-qubit Hamiltonian. But the time necessary to complete the gate operation depends inversely on the magnitude of the interaction term:

$${t}_{gate} = \frac{π}{2 λ} \qquad Eq . 2$$

Thus, shorter gate times (useful for performing more quantum operations) require larger interaction terms. But larger interaction terms require larger-amplitude DD drives, which can cause significant leakage errors (e.g., increased probabilities of transitions to quantum states other than those used for computation). Furthermore, hardware limitations can restrict achievable DD amplitudes. Such hardware limitations can include power restrictions on the waveform generator that creates the DD drive, restrictions on the amount of heat generated by the DD drive (e.g., arising from limitations in cooling the cryogenic environment in which the qubits operate), the effect of filters used to reduce noise in the cryogenic environment, or other hardware limitations.

The disclosed embodiments include improved DD drive systems and methods not constrained by Eq. 1. The envisioned DD drives include continuous phase drive (e.g., drives with constant phase: drives lacking a phase shift, such as a phase reversal midway through the gate time; or the like), in some embodiments. The envisioned DD drives can synchronize an integer number of Rabi periods to the gate time, in various embodiments. In particular, the disclosed embodiments envision fine tuning the DD amplitude and removing the phase flip in the dynamically decoupling drive. As described herein, gate fidelity can oscillate with the DD amplitude. Thus, rather than relying on large amplitudes, the DD amplitude can be selected to match a peak in the fidelity-amplitude relationship, thereby avoiding the large amplitude requirements of conventional DD drive approaches. Furthermore, by removing the phase flip, the minimal DD amplitude necessary for a high-fidelity gate can be substantially reduced. By operating at lower DD amplitudes, leakage errors can be significantly reduced. Furthermore, the DD amplitudes described herein can be achieved using existing experimental equipment. The disclosed embodiments therefore enable dramatic reduction the DD amplitudes, and support high-fidelity quantum gates having short gate times. While described for convenience with regards to controlled-Z gates, the disclosed embodiments are not so limited.

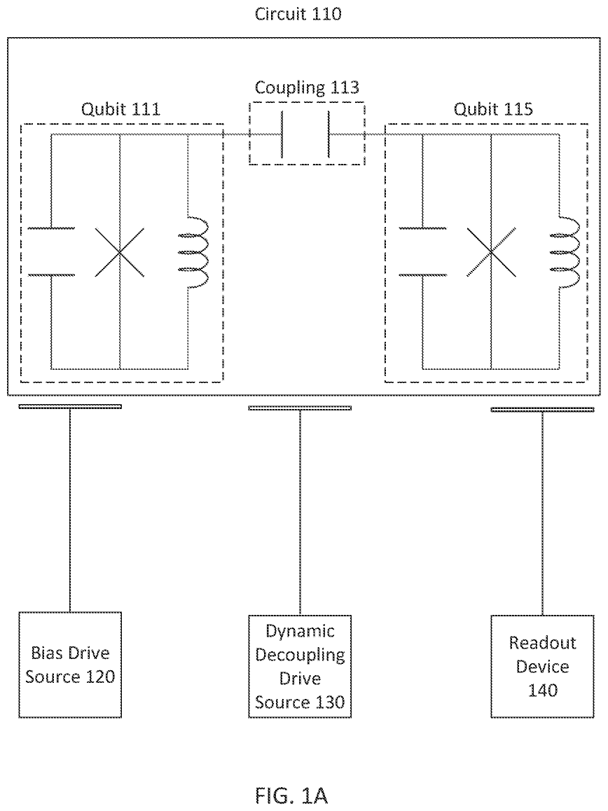

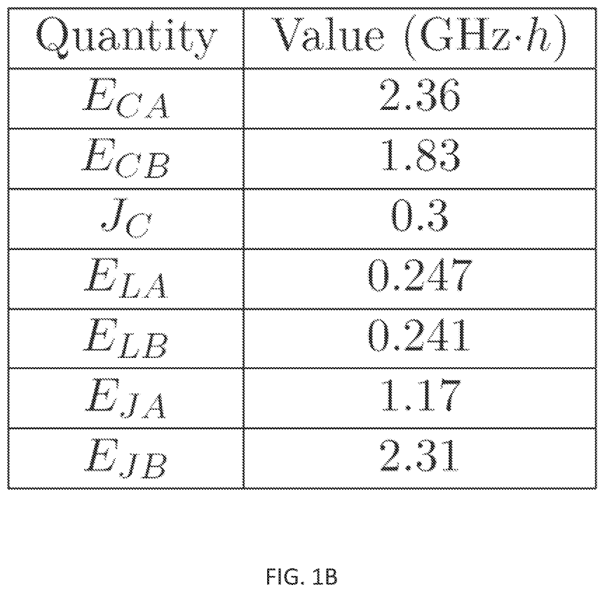

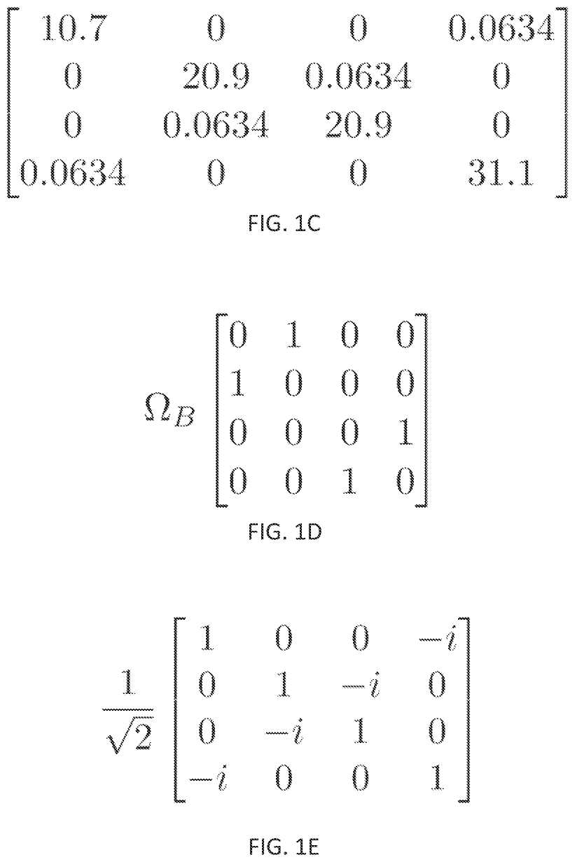

FIG. 1A depicts a schematic of an exemplary circuit 110 suitable for implementing a controlled-Z gate, in accordance with disclosed embodiments. Circuit 110 can include two fluxonium qubits (qubit 111 and qubit 115). Each fluxonium qubit can be implemented using a Josephson junction shunted by a capacitor and an inductor. Each of these inductors can be realized by an array of Josephson junctions. Each of the qubits can be constructed to operate at a local minimum in frequency with regards to a biasing magnetic flux. In this non-limiting example, the local minimum for qubit 115 can be lower than the local minimum for qubit 111. The qubits can be coupled by a coupling 113. Coupling 113 can be implemented using a capacitor. In some instances, circuit 110 can be configured to enable transverse resonant coupling (e.g., charge-coupled, or the like) between the qubits. However, such coupling may require alignment of the qubit frequencies. When the gate is not in operation, the qubits can be maintained as different frequencies.

In some embodiments, circuit 110 can be realized using a chip containing the qubits and the coupling between the qubit. In some embodiments, the chip can include couplings to bias drive source 120, DD drive source 130, and readout device 140.

Bias drive source 120 can be coupled to circuit 110. In some embodiments, bias drive source 120 can be configured to provide a bias flux to at least one of qubit 111 or qubit 115. Consistent with disclosed embodiments, qubit 111 and qubit 115 can be configured with different frequencies. Bias drive source 120 can be configured to drive the qubits into resonance, enabling gate operation. In some instances, bias drive source 120 can cause a magnetic bias flux to be provided to the qubit with the lower frequency (e.g., qubit 115 in this non-limiting example). In some embodiments, the bias flux can be provided by passing current through a coil external to circuit 110. In various embodiments, the bias flux can be provided by passing current through a coil on the chip. The disclosed embodiments are not limited to a particular method of biasing the qubits.

DD drive source 130 can be coupled to circuit 110. In some embodiments, DD drive source 130 can be configured to provide a continuous microwave drive to a qubit. The microwave drive can be alternating (e.g., sinusoidal, square wave, biphasic pulse train, or the like). In this example, the disclosed embodiments are described with respect to a DD drive provided to a single qubit. The DD drive can be applied to the same qubit as the bias flux. The bias flux can increase the sensitivity of the qubit to flux noise by tuning the qubit out of a local frequency minimum with respect to flux (in which it was less sensitive to flux noise). The DD drive can at least partially address this increased noise sensitivity by mitigating the effects of certain noise (e.g., noise having a correlation time longer than the period of a Rabi oscillation). In some embodiments, the bias flex and the DD drive can be applied to the lower frequency qubit (e.g., qubit 115). Additionally or alternatively, applying the DD drive to only one qubit can reduce calibration and control requirements for circuit 110, as well as reducing amplitude tuning requirements. Furthermore, leakage errors due to the drive applied to qubit 111 can be avoided. However, the disclosed embodiments are not limited to applying a DD drive to only one qubit. In some embodiments, two different microwave drives can be provided to the two different qubits in circuit 110.

Readout device 140 can be coupled to circuit 110. Readout device 140 can enable a computing device to perform a measurement on one or more qubits of the circuit. In some instances, a quantum computing device including circuit 110 can use readout device 140 to measure the state of one or more qubits of circuit 110 upon completion of a sequence of quantum operations. The sequence of quantum operations can include performance of the controlled-Z gate (e.g., by performing a DDCZ gate and additional single-qubit gates, or the like). In some embodiments, readout device 140 can include an arbitrary waveform generator configured to provide a probe signal (e.g., a microwave probe tone) to a coupled resonator. In various embodiments, readout device 140 can include a detector configured to determine an amplitude and phase of an output signal received from the coupled resonator in response to provision of the microwave probe tone.

In some embodiments, a single device can perform the functions of two or more of bias drive source 120, DD drive source 130, and readout device 140. For example, DD drive source 130 can provide the DD drive and the probe signal. As an additional example, the current creating the bias flus can be combined with the DD drive.

A Hamiltonian can be constructed for circuit 110, assuming the DD drive is applied only to qubit 115 and is in the frame rotating with the qubits, with the rotating wave approximation applied:

$$H = λ ( {σ}_{A}^{+} {σ}_{B}^{-} + {σ}_{A}^{-} {σ}_{B}^{+} ) + {Ω}_{B} ( {σ}_{B}^{+} + {σ}_{B}^{-} ) \qquad Eq . 3$$

where λ is the coefficient for the interaction term, σ⁺≡|1 [symbol] [symbol] 0| (e.g., σ⁺ is a matrix that when given the quantum state |0 [symbol] , returns the quantum state |1 [symbol] ) and σ⁻≡|0 [symbol] [symbol] 1| (e.g., σ⁻ is a matrix that when given the quantum state |1 [symbol] , returns the quantum state |0 [symbol] ), and Ω_{B} is the amplitude of the DD drive. The first term of Eq. 3 is referred to herein as the “static Hamiltonian” and the second term is referred to herein as the “DD Hamiltonian”. The phases on the |0 [symbol] and |1 [symbol] states are chosen such that λ is positive. The duration of the DD drive can be determined using Eq. 2, above.

A circuit Hamiltonian can be constructed for circuit 110 based on the elements depicted in FIG. 1, as follows:

$${H}_{c} = 4 {E}_{CA} {n}_{A}^{2} + {J}_{C} {n}_{A} {n}_{B} + 4 {E}_{CB} {n}_{B}^{2} + 0.5 {E}_{LA} {ϕ}_{A}^{2} + 0.5 {E}_{LB} {ϕ}_{B}^{2} - {R}_{JA} cos ( {ϕ}_{A} - {ϕ}_{ext , A} ) - {E}_{JB} cos ( {ϕ}_{B} - {ϕ}_{ext , B} ) \qquad Eq . 4$$

In this Hamiltonian, n_{A} is the charge on the junction capacitance of qubit 111, expressed as a number of Cooper pair charges; n_{B} is the charge on the junction capacitance of qubit 115, expressed as a number of Cooper pair charges; ϕ_{A} is the loop flux through the inductor of qubit 111, expressed in units that coincide with the units of the phase difference across the Josephson junction of qubit 111; ϕ_{B} is the loop flux through the inductor of qubit 115, expressed in units that coincide with the units of the phase difference across the Josephson junction of qubit 115: E_{CA} is an energy scale coefficient for the junction capacitance of qubit 111; E_{CB} is an energy scale coefficient for the junction capacitance of qubit 115; E_{jA} is an energy scale coefficient for the Josephson junction in qubit 111; and E_{jB} is an energy scale coefficient for the Josephson junction in qubit 115. J_{C} is an energy scale coefficient for the coupling capacitance. ϕ_{ext,A} can be a bias flux for qubit 111 and can be set to π, situating the qubit at its local minimum frequency with respect to magnetic flux. ϕ_{ext,B} can be a bias flux for qubit 115 and can be set to a value that causes the frequency of qubit 115 to match the frequency of qubit 111.

FIG. 1B depicts a table of values for an exemplary instance of the controlled-Z gate depicted in FIG. 1A, in accordance with disclosed embodiments. With such values, ϕ_{ext,B} can be set to 1.97 to match frequencies between the qubits in circuit 110.

The circuit Hamiltonian can be projected onto the span of the two lowest states of the circuit (the states used for computation) by sandwiching H_{C} with projectors onto these first two states. The result is the matrix of Hamiltonian coefficients depicted in FIG. 1C. The effect of the DD drive can be incorporated into Eq. 4 by adding a term proportional to ng. Once the resulting circuit Hamiltonian is projected onto the span of the two lowest states of the circuit, the DD drive term takes on the form of the matric depicted in FIG. 1D. By expressing the resulting Hamiltonian in the two qubits rotating frame of reference and applying the rotating wave approximation, the Hamiltonian depicted in Eq. 1 can be obtained, with the interaction term having the value λ=0.0634 GHz·h.

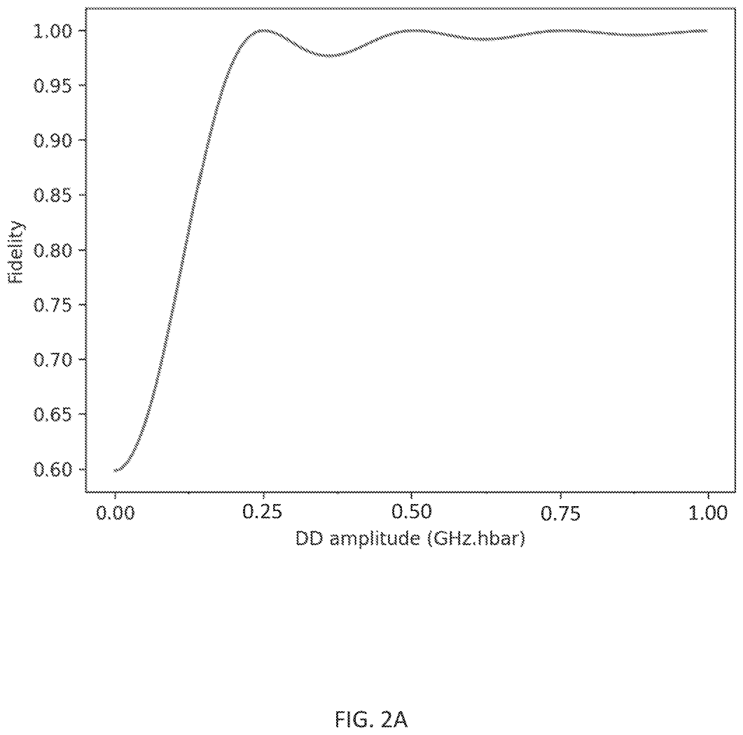

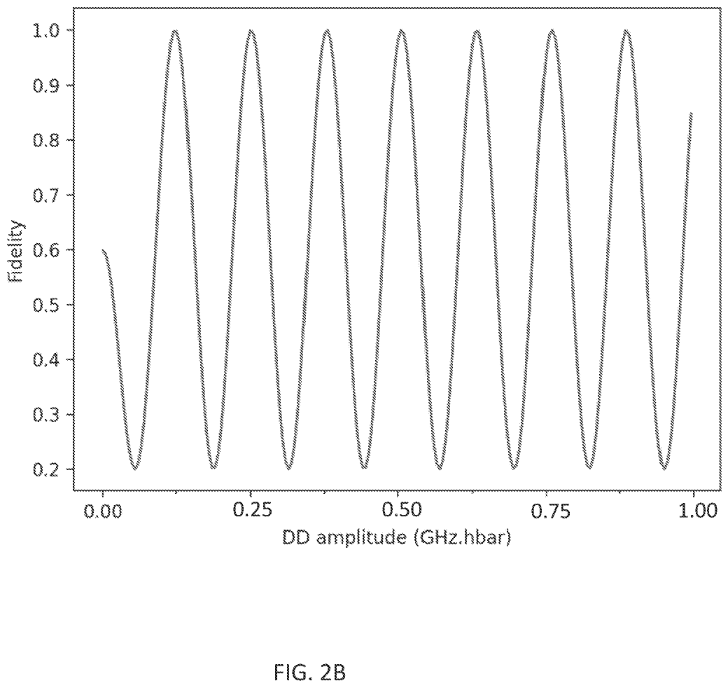

A time evolution operator can be determined for the gate time given in Eq. 2 for different values of the DD amplitude. An average fidelity with the unitary matrix corresponding to the DDCZ gate (the unitary matrix depicted in FIG. 1E) can be computed using the time evolution operator. In some embodiments, the fidelity of the DDCZ gate can form a bound on the fidelity of a CZ gate constructed using the DDCZ gate. In this non-limiting example, the average fidelity is computed as the Haar average over states. The gate fidelities and state evolutions depicted in FIGS. 2A to 4C are generated using gate times as given in Eq. 2.

FIG. 2A depicts DDCZ gate fidelity as a function of DD drive amplitude for a conventional DD drive, without including leakage effects. The DD drive providing in this example is continuous and sinusoidal. The phase of the DD drive is reversed at the midpoint of the gate time, as discussed above. As can be observed from the graph, the fidelity trace resembles an underdamped step response, with a first peak at approximately 0.25 GHz·ℏ (or about 4 times the amplitude of the interaction term in the Hamiltonian) and quasi periodic oscillations that decrease with increasing drive amplitude.

FIG. 2B depicts DDCZ gate fidelity as a function of DD drive amplitude, without considering leakage effects and in accordance with disclosed embodiments. In this example, a sinusoidal dynamical drive is provided without phase reversal. As shown, fidelity in this example is a quasi-periodic function of amplitude (as the period of oscillation is not constant between peaks). The approximate period of the oscillations in FIG. 2B is about half the approximate period of the oscillations in FIG. 2A. Accordingly, the first maxima in the fidelity trace is reached with a DD amplitude of approximately 0.125 GHz·ℏ (or about 2 times the amplitude of the interaction term in the Hamiltonian). DD drives consistent with the disclosed embodiments can have amplitudes corresponding to peaks in the fidelity trace. Unlike the relationship depicted in FIG. 2A, however, fidelity varies greatly with DD amplitude. Thus, DD drives in accordance with disclosed embodiments may require additional calibration to ensure the fidelity of the DDCZ gate.

Leakage of the qubits in circuit 110 to states outside the intended computational subspace (e.g., the space of |00 [symbol] , |01 [symbol] , |10 [symbol] , and |11 [symbol] ) can reduce the fidelity of the DDCZ gate implemented using circuit 110. An upper bound on the fidelity of the DDCZ gate in the presence of such leakage can be established via Cauchy-Schwartz as:

$$Average Fidelity \leq 1 - L ≡ \frac{{‖ {\prod }_{S} V {∮}_{S} ‖}_{F}^{2}}{4} \qquad Eq . 5$$

In this bound, Π_{S} is the projector onto the computational subspace:

$${\prod }_{S} = \vert 00 〉 〈 00 \vert + \vert 01 〉 〈 01 \vert + \vert 10 〉 〈 10 \vert + \vert 11 〉 〈 11 \vert \qquad Eq . 6$$

while V is the implemented unitary (which may have leakage errors), and ∥⋅∥_{F}² denotes the squared Frobenius norm. In other words, L is the population outside the computational subspace averaged over the states resulting from the implemented unitary acting on states in the computational subspace.

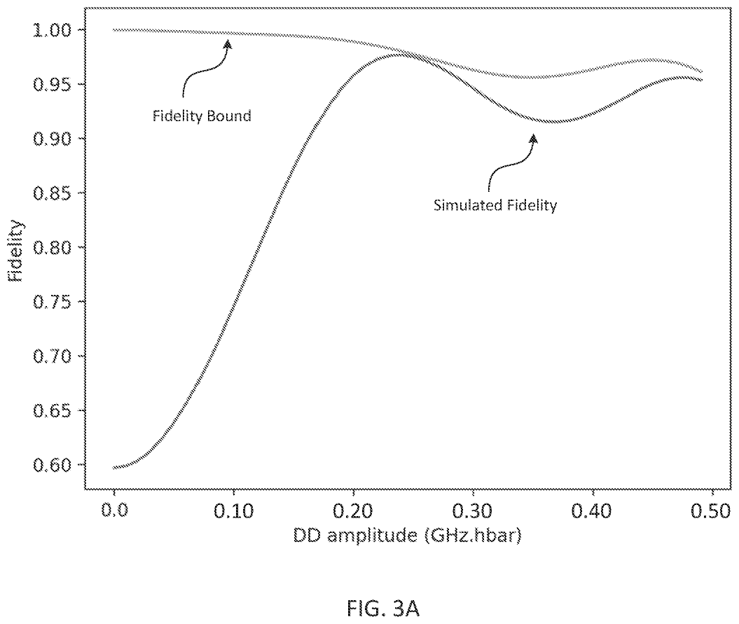

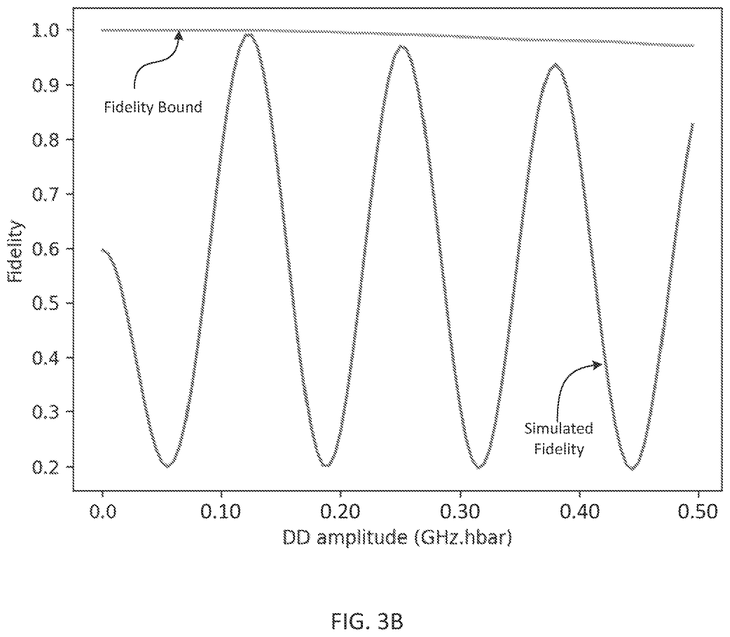

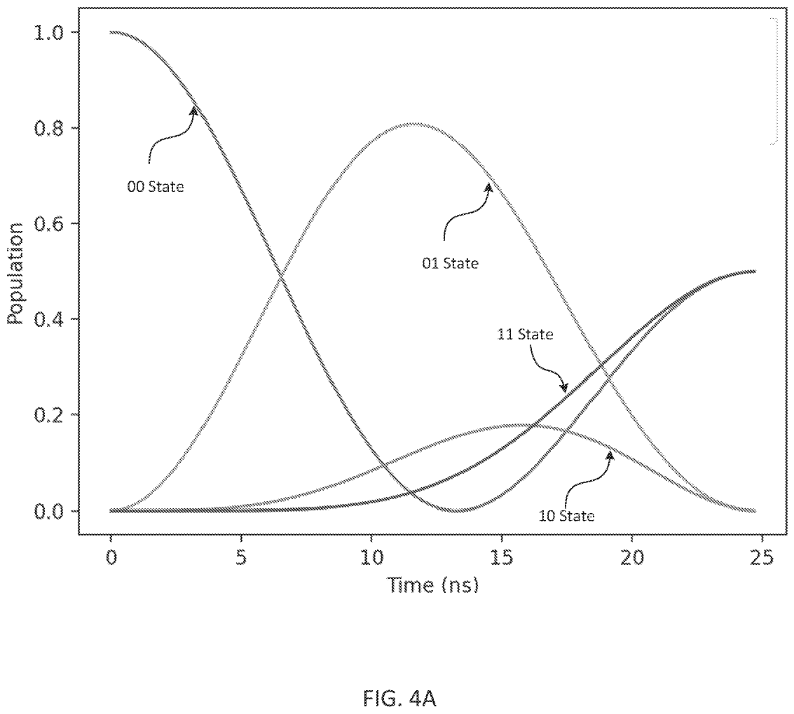

FIG. 3A depicts DDCZ gate fidelity as a function of DD drive amplitude for a conventional DD drive, including leakage effects. As in FIG. 2A, this conventional drive is sinusoidal and includes a phase reversal midway through the gate time. However, FIG. 3A differs from FIG. 2A in that a higher energy level for each qubit in circuit 110 is modeled in the simulation. As depicted in FIG. 3A, the upper bound on gate fidelity starts at approximating unity and decreases with increasing DD amplitude (as transitions to states outside the computational subspace become more likely). The simulated gate fidelity under this model is also depicted, increasing from 0.6 to more than 0.95 as the DD amplitude increases toward 0.20 GHz·ℏ (or approximately 3 times the magnitude of the interaction term in the Hamiltonian). The location of the peaks in the fidelity trace shifts towards higher DD amplitudes, as compared to FIG. 2A. This figure further demonstrates that the conventional DD drive results requires drive amplitudes that can result in reduced gate fidelity.

FIG. 3B depicts DDCZ gate fidelity as a function of DD drive amplitude including leakage effects, and in accordance with disclosed embodiments. As in FIG. 3A, a higher energy level for each qubit in circuit 110 is modeled in the simulation. However, the drive does not include a phase reversal midway through the gate time. As depicted in FIG. 3B, the upper bound on gate fidelity starts at approximating unity and decreases with increasing DD amplitude (as transitions to states outside the computational subspace become more likely). However, the decrease is less rapid than observed in FIG. 3A. The simulated gate fidelity increases to a peak at approximately 0.125 GHz·ℏ (or approximately 2 times the magnitude of the interaction term in the Hamiltonian). As in FIG. 3A, the fidelity trace in FIG. 3B exhibits a shift in the fidelity peaks towards increasing DD amplitudes.

In general, the leakage upper bound decreases with DD amplitude, worsening leakage error. This decrease does not appear strictly monotonic, as the population that leaks outside the computational subspace may return after some time. Furthermore, the peaks in the trace of simulated fidelity as a function of DD amplitude closely approach the upper bound. This result suggests that gate fidelity may be limited by leakage to states outside the computational subspace. In turn, this suggests that implementations using lower DD amplitudes, such as the disclosed embodiments, can support higher fidelities than conventional approaches, improving the performance of quantum computers. As shown, improved fidelity can be achieved by tuning the DD amplitude to a peak in the fidelity-amplitude relationship. By removing the phase flip, even lower DD amplitudes and higher fidelities can be achieved: the first peak in FIG. 3B has a higher fidelity at a lower DD amplitude than the first peak in FIG. 3A.

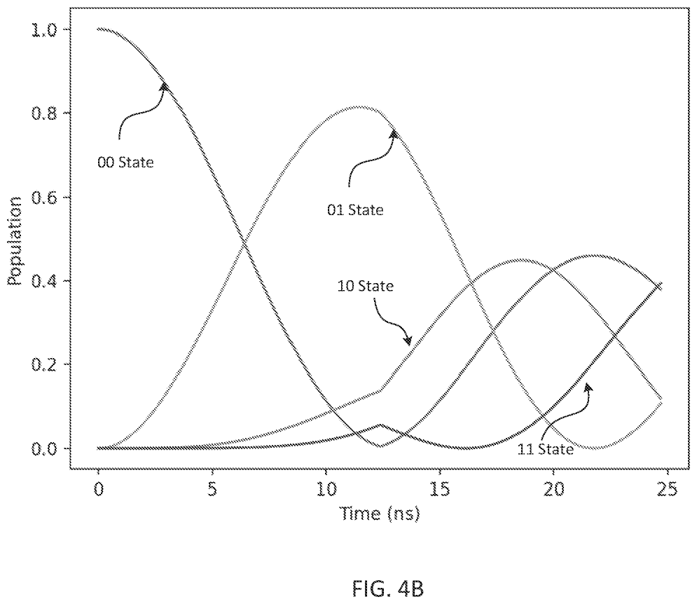

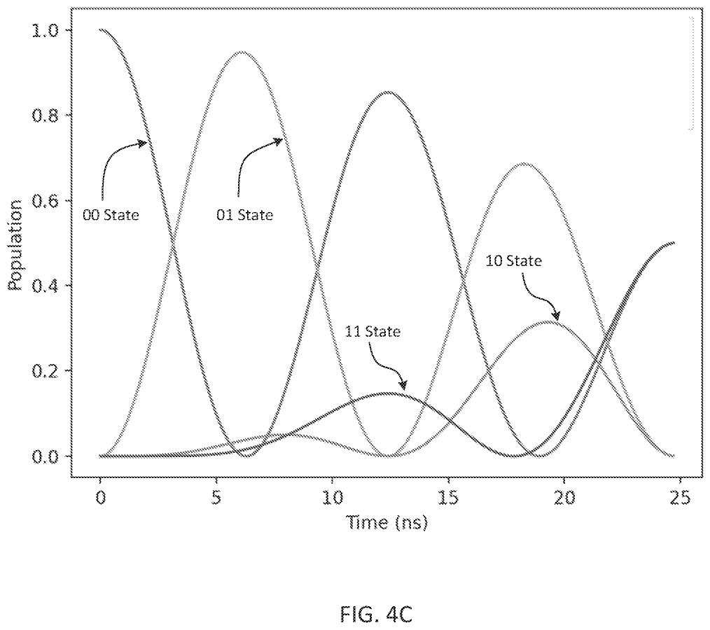

Consistent with disclosed embodiments, the DD drive can be tuned to synchronize the Rabi oscillation induced by the DD drive with the gate time. FIGS. 4A and 4B depict the populations of states for circuit 110 using either DD drive including a phase flip (FIG. 4B) and DD drive without a phase flip (FIG. 4A). In each figure, the independent variable is time and the dependent variable is the population in each of the four states in the computational subspace. In both of these examples, the initial population is entirely in the |00 [symbol] state. The desired output at the end of the operation is for the populations to be split evenly between the |00 [symbol] state and the |11 [symbol] state.

FIG. 4A depicts state evolution of a DDCZ gate, in accordance with disclosed embodiments. The amplitude of the DD drive is chosen as 0.125 GHz·ℏ, based on the value of the first peak in FIG. 2B. The evolution of the populations can be interpreted via the Suzuki-Trotter expansion:

$${e}^{- {i [ λ ( {σ}_{A}^{+} {σ}_{B}^{-} + {σ}_{A}^{-} {σ}_{B}^{+} ) + {Ω}_{B} ( {σ}_{B}^{+} + {σ}_{B}^{-} ) ]}^{t}} = {lim}_{n \to ∞} {[ {e}^{- i λ ( {σ}_{A}^{+} {σ}_{B}^{-} + {σ}_{A}^{-} {σ}_{B}^{+} ) t / n} {e}^{- i {Ω}_{B} ( {σ}_{B}^{+} + {σ}_{B}^{-} ) t / n} ]}^{n} \qquad Eq . 7$$

This equation states that the matrix exponentiation of the Hamiltonian for circuit 110 (Eq. 3) is equal, in the limit as n approaches infinity, to the product of two matrix exponentiations: a matrix exponentiation corresponding to the static Hamiltonian, and a matrix exponentiation corresponding to the DD drive Hamiltonian. As an intuitive explanation, consider alternatively and infinitesimally applying the DD drive Hamiltonian and the static Hamiltonian.

The population evolution between the states can then be considered in terms of three component dynamics:

1. A Rabi oscillation between the |00 [symbol] and |01 [symbol] states, arising from the DD drive Hamiltonian.

2. An oscillation between the |01 [symbol] and |10 [symbol] states, arising from the static Hamiltonian.

3. A Rabi oscillation between the |10 [symbol] and |11 [symbol] states, also arising from the DD drive Hamiltonian (as the DD drive can cause the state of qubit 115 to oscillate between (0) and (1), independent of the state of qubit 111).

As can be seen, the Rabi oscillation in the second qubit between the |00 [symbol] and |01 [symbol] states causes the population in the |00 [symbol] state to decrease and the population in the |01 [symbol] state to increase. The transfer term in the static Hamiltonian begins transferring the population in the |01 [symbol] state to the |10 [symbol] state. Finally, another Rabi oscillation in the second qubit causes the population in the |10 [symbol] state to decrease and the population in the |11 [symbol] state to increase.

The correct unitary (depicted in FIG. 1E) can be obtained by synchronizing the Rabi oscillation period for these first and second dynamics to the gate time (as given in Eg. 2). Therefore, by setting:

$$π / {Ω}_{B} \approx π / 2 λ \qquad Eq . 8$$

$$or$$

$${Ω}_{B} \approx 2 λ \qquad Eq . 9$$

a high-fidelity gate can be obtained. The above equations 8 and 9 can be approximate, as the DD drive Hamiltonian and the static Hamiltonian do not commute, therefore these matrix exponentiations are not independent. In the example explored herein, 2λ=2*0.0634 GHZ·ℏ=0.127 GHz·ℏ, while Ω_{B} at the peak in FIG. 2A was 0.122 GHz·ℏ. In some embodiments, however, selecting a drive value within a certain percentage of 2λ will yield a DDCZ gate of suitable fidelity. In some instances, this percentage could be between 5% and 10%.

Furthermore, the other peaks seen in FIG. 2B correspond to approximately synchronizing an integer number of Rabi oscillations to the gate time. Thus, by fine tuning the DD amplitude and without using a phase flip, high fidelity DDCZ gate operations can be achieved.

FIG. 4B depicts state evolution of a DDCZ gate for a conventional DD drive. For comparative purposes, the amplitude of the DD drive is set at approximately 0.125 GHz·ℏ, similar to the drive amplitude used in generating FIG. 4A. As seen in FIG. 2A, this amplitude does not result in a high-fidelity gate. The population evolution depicted in FIG. 4B can also be can also be explained via the Suzuki-Trotter expansion. In this simulation, the first half of the evolution is exactly the same as when the improved DD drive is applied. But the second half of the evolution is different, due to the phase flip used by conventional DD drives. Applying a DD drive with the opposite phase has the effect of reversing the Rabi oscillations, as is evident in FIG. 4B. In particular, halfway through the gate, the Rabi oscillation between |10 [symbol] and |11 [symbol] is reversed, thereby significantly interfering with the synchronization of the static Hamiltonian evolution with the Rabi oscillations.

FIG. 4C depicts state evolution of a DDCZ gate for a conventional DD drive, with a DD amplitude selected to match a peak in the fidelity-amplitude trace depicted in FIG. 2A. In this example, the DD drive amplitude is Ω_{B}=0.253 GHz·ℏ which is approximately 4λ=4*0.0634 GHz·ℏ=0.254 GHz·ℏ. As depicted in FIG. 4C, both the |00 [symbol] to |01 [symbol] and the |10 [symbol] and |11 [symbol] Rabi oscillations are at critical points (e.g., local minima or maxima). Thus, the phase flip, reversing the Rabi oscillations, does not affect the dynamics of these oscillations. In this manner, the gate time is synchronized to two Rabi oscillations. Thus, the first peak in fidelity when using conventional drive occurs at approximately twice the DD amplitude of the first peak in fidelity when using continuous phase drive (e.g., drive with constant phase, or drive without a phase flip, or the like).

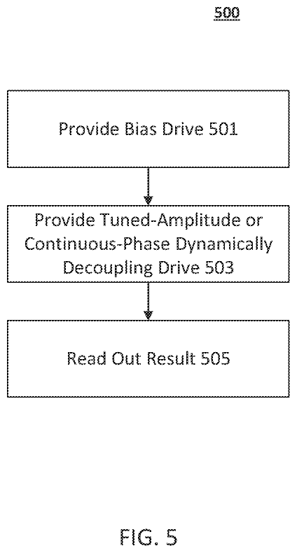

FIG. 5 depicts a flowchart of an exemplary method 500 for operating a DDCZ gate, in accordance with disclosed embodiments. Method 500 can include the steps of providing a bias drive, providing a tuned or continuous phase dynamically decoupling drive, and reading out the result of the controlled-Z gate operation. Method 500 can be performed by a quantum computing system. The quantum computing system can include superconducting circuit suitable for implementing a controlled-Z gate, such as circuit 110 depicted in FIG. 1A. The circuit can include at least two qubits. Consistent with disclosed embodiments, the qubits can be flux qubits, charge qubits, phase qubits, or the like. In various embodiments, the qubits can be transmon qubits or fluxonium qubits. The qubits can be coupled (e.g., transversely coupled). The quantum computing system can include a bias drive source (e.g., bias drive source 120, or the like), a DD drive source (e.g., DD drive source 130, or the like), and a readout device (e.g., readout device 140). The conventional computing system can include a protected environment for isolating the DDCZ gate, such as a dilution refrigerator or other suitable cryogenic environment. The quantum computing system can include a conventional computing device (e.g., a digital computing device comprising a processor and one or more memories or caches, or the like). Consistent with disclosed embodiments, the conventional computing device can orchestrate the operations of the bias drive source, dynamically decoupling drive source, and readout device.

Consistent with disclosed embodiments, prior to performance of method 500, the qubits of the circuit may be in a particular state. This state can be predetermined (e.g., the state can be an initial state, such as a ground state, or the like). The state can be the result of one or more prior computations. In some embodiments, for example, gate operations can be applied to one or more of the qubits of circuit 110 to set the states of these gates (e.g., quantum M, MT, N, X, Y, Z, phase, or CNOT gate operations can be applied to one or more qubits to set the states of these qubits). In accordance with method 500, the quantum computing system can perform the DDCZ gate operation on the initial state of the qubits to obtain a new state.

In step 501, the conventional computing device can provide instructions to the bias drive source. The instructions can include commands (e.g., data values representing a “start” command, or the like), triggering signals (e.g., timing pulses, or the like), code, or the like. The instructions can cause the bias drive source to apply a magnetic flux to one of the qubits in the gate (e.g., the lower frequency qubit). Applying a magnetic flux can include providing current to a coil, inductor, electromagnet, or the like to cause a magnetic flux to be applied to the one of the qubits. The magnitude of the applied magnetic field can be selected to bring a frequency of the one of the qubits into resonance with a frequency of another one of the qubits.

In some embodiments, a baseline magnetic flux may be applied to one of the qubits (or to both qubits) and applying a magnetic flux can include incrementing (or decrementing) this baseline magnetic flux (e.g., by incrementing or decrementing a current provided to the coil, inductor, electromagnet, or the like).

In step 503, the conventional computing device can provide instructions to the DD drive source. The instructions can include commands (e.g., data values representing a “start” command, or the like), triggering signals (e.g., timing pulses, or the like), code, or the like. The instructions can cause the drive source to apply a DD drive to at least one qubit (e.g., the same qubit as the magnetic flux, another qubit affected by the DDCZ gate operation, multiple qubits affected by the DDCZ gate operation, or the like). The DD drive can be alternating, as described herein. The DD drive can be a continuous phase drive, as described herein. As described herein, the magnitude of the DD drive can depend on a magnitude of an interaction term between the qubits in a Hamiltonian of controlled-Z gate, the Hamiltonian specified for a frame rotating with the qubits.

In some embodiments, a duration and a magnitude of the DD drive can be configured to synchronize the DD drive duration to an integer number of Rabi oscillations. For example, the magnitude of the DD drive can be selected such that n∈ [symbol] ⁺ Rabi oscillations (e.g., between the |10 [symbol] and |11 [symbol] states and between the |00 [symbol] and |01 [symbol] states) occur during provision of the DD drive. In some instances, the magnitude of the DD drive can be selected such that one, two, or three Rabi oscillations occur during provision of the DD drive.

In various embodiments, a magnitude of the DD drive can correspond to a peak in a relationship between the DD magnitude and a fidelity of the dynamic-decoupled controlled-Z gate. The peak can be the first such peak in the relationship, or a later peak. In the non-limiting example provided herein, in which the interaction term was 0.0634 GHz·ℏ, the peak in the fidelity for conventional DD drive was 0.253 GHz·ℏ, while the peak in the fidelity for continuous phase DD drive was 0.128 GHz·ℏ. An appropriate DD amplitude can be determined by selecting an initial DD amplitude based on the equations provided herein and then fine tuning the DD drive amplitude to obtain the desired degree of gate fidelity. In some embodiments, such fine-tuning can occur as part of an initial configuration of the quantum computing device prior to performance of the sequence of quantum computing operations. In some instances, the magnitude of the DD drive can be between one and three times the magnitude of the interaction term.

In some embodiments, additionally or alternatively to tuning a DD amplitude, a duration of the gate can be fine-tuned. In some instances, as described herein, a duration of the DD drive can depend inversely on the magnitude of the interaction term in the circuit Hamiltonian. In some embodiments, the DD drive can be applied for a duration approximately equal to (e.g., within 10%, or the like) the quotient of pi divided by the magnitude of the interaction term in the circuit Hamiltonian, in accordance with Eq. 2. For example, when the quotient of pi divided by the magnitude of the DD drive is 25 ns, the duration can be within 22.5 ns to 27.5 ns.

In some embodiments, the magnetic flux and the DD drive can be coincident. In various embodiments, the magnetic flux can begin before the DD drive or can end after the DD drive. In some embodiments, the cessation of the bias flux can cause the two qubits to fall out of resonance.

In step 505, the quantum computing device can obtain results based, at least in part, on the operation of the DDCZ gate. In some embodiments, the controlled-Z gate can be the final gate computed prior to reading out the results. In various embodiments, one or more other gates or operations may be performed using the qubits in the controlled-Z gate prior to reading out a state of the quantum computing system. In some instances, the state of the quantum computing system can depend, at least in part, on the performance of the controlled-Z gate. For example, the conventional computing device can cause the quantum computer to execute a quantum computing algorithm. Executing the controlled-Z gate can be a step in the quantum computing algorithm. The results of the quantum computing algorithm can be read out from the quantum computing system when the algorithm has completed execution.

The results can be read out using readout device 140. In some embodiments, the conventional computing device can provide instructions to the readout device to read the results of the quantum computation. The results can be read from one or more of the qubits of the controlled-Z gate, or from one or more other qubits of the quantum computing device.

In some embodiments, readout device 140 can be used for dispersive readout of the states of the qubits, or another suitable readout methodology. Readout device 140 can be coupled to one or more readout resonators. Each of the one or more readout resonators can be coupled to a qubit of circuit 110. A state of the qubit can be inferred from a state-dependent frequency shift of the coupled readout resonator. Readout device 140 can provide a probe signal to the coupled readout resonator and measure an output signal received from the coupled readout resonator. A state of the qubit can be determined from the amplitude and phase of the output signal. The output signal can be a reflected or transmitted signal, in accordance with disclosed embodiments.

In some embodiments, a non-transitory computer-readable storage medium including instructions is also provided, and the instructions may be executed by a device (such as the disclosed encoder and decoder), for performing the above-described methods. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same. The device may include one or more processors (CPUs), an input/output interface, a network interface, and/or a memory.

The foregoing descriptions have been presented for purposes of illustration. They are not exhaustive and are not limited to precise forms or embodiments disclosed. Modifications and adaptations of the embodiments will be apparent from consideration of the specification and practice of the disclosed embodiments. For example, the described implementations include hardware, but systems and methods consistent with the present disclosure can be implemented with hardware and software. In addition, while certain components have been described as being coupled to one another, such components may be integrated with one another or distributed in any suitable fashion.

Moreover, while illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application, which examples are to be construed as nonexclusive. Further, the steps of the disclosed methods can be modified in any manner, including reordering steps or inserting or deleting steps.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

The features and advantages of the disclosure are apparent from the detailed specification, and thus, it is intended that the appended claims cover all systems and methods falling within the true spirit and scope of the disclosure. As used herein, the indefinite articles “a” and “an” mean “one or more.” Similarly, the use of a plural term does not necessarily denote a plurality unless it is unambiguous in the given context. Further, since numerous modifications and variations will readily occur from studying the present disclosure, it is not desired to limit the disclosure to the exact construction and operation illustrated and described, and accordingly, all suitable modifications and equivalents may be resorted to, falling within the scope of the disclosure.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A. B, or C, then, unless specifically stated otherwise or infeasible, the database may include A, or B, or C, or A and B, or A and C, or B and C, or A and B and C.

It is appreciated that the above-described embodiments can be implemented by hardware, or software (program codes), or a combination of hardware and software. If implemented by software, it may be stored in the above-described computer-readable media. The software, when executed by the processor can perform the disclosed methods. The computing units and other functional units described in this disclosure can be implemented by hardware, or software, or a combination of hardware and software. One of ordinary skill in the art will also understand that multiple ones of the above-described modules/units may be combined as one module/unit, and each of the above-described modules/units may be further divided into a plurality of sub-modules/sub-units.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

The embodiments may further be described using the following clauses:

1. A quantum computing system for performing a dynamically decoupled controlled-Z gate operation, comprising: a superconducting circuit comprising: a first qubit:
a second qubit transversely coupled to the first qubit; and at least one computing device configured to: provide, to a first drive source, first instructions causing the first drive source to apply an external magnetic flux to the second qubit to bring a frequency of the second qubit into resonance with a frequency of the first qubit; and provide, to a second drive source, second instructions causing the second drive source to apply a continuous alternating drive with continuous phase to the second qubit.

2. The quantum computing system of clause 1, wherein: a duration and a magnitude of the continuous alternating drive is configured to synchronize a gate time of the dynamically decoupled controlled-Z gate operation to an integer number of Rabi oscillation periods

3. The quantum computing system of clause 1, wherein: a magnitude of the continuous alternating drive is selected based on a magnitude of an interaction term between the first qubit and the second qubit in a Hamiltonian of the superconducting circuit, the Hamiltonian specified for a frame rotating with the first and second qubits.

4. The quantum computing system of clause 3, wherein: the magnitude of the continuous alternating drive is between one and three times the magnitude of the interaction term.

5. The quantum computing system of any one of clauses 1 to 4, wherein: a duration of the continuous alternating drive is inversely based on a magnitude of the continuous alternating drive.

6. The quantum computing system of any one of clauses 1 to 5, wherein: a duration of the continuous alternating drive is selected to be within 10% of a quotient of pi divided by a magnitude of the continuous alternating drive.

7. The quantum computing system of any one of clauses 1 to 5, wherein: a magnitude of the continuous alternating drive is selected to correspond to a peak in a relationship between the magnitude and a fidelity of the dynamically decoupled controlled-Z gate operation.

8. The quantum computing system of clause 7, wherein: the peak comprises a first peak in the relationship.

9. The quantum computing system of any one of clauses 1 to 8, wherein: the first qubit and the second qubit are both fluxonium qubits.

10. The quantum computing system of any one of clauses 1 to 9, wherein: the at least one computing device is further configured to provide, after providing the second instructions to the second drive source, third instructions to read out a state of the quantum computing system.

11. A method for performing a dynamically decoupled controlled-Z gate operation, comprising: providing, by a first drive source to a second qubit of a superconducting circuit of a quantum computing system, an external magnetic flux to tune a frequency of the second qubit to a frequency of a first qubit, the first qubit being transversely coupled to the second qubit; providing, by a second drive source to the second qubit, a continuous alternating drive, a magnitude of the continuous alternating drive corresponding to a peak in a relationship between the magnitude and a fidelity of the dynamically decoupled controlled-Z gate operation; and reading out, after providing the second drive source, a state of the quantum computing system.

12. The method of clause 11, wherein: the magnitude of the continuous alternating drive is selected based on a magnitude of an interaction term between the first qubit and the second qubit in a Hamiltonian of the superconducting circuit, the Hamiltonian specified for a frame rotating with the first and second qubits.

13. The method of clause 12, wherein: the magnitude of the continuous alternating drive is between one and three times the magnitude of the interaction term.

14. The method of any one of clauses 11 to 13, wherein: a duration of the continuous alternating drive is based inversely on the magnitude of the continuous alternating drive.

15. The method of any one of clauses 11 to 14, wherein: a duration of the continuous alternating drive is selected to be within 10% of a quotient of pi divided by the magnitude of the continuous alternating drive.

16. The method of any one of clauses 11 to 15, wherein: the peak comprises a first peak in the relationship.

17. The method of any one of clauses 11 to 16, wherein: a duration and the magnitude of the continuous alternating drive are selected to synchronize a gate time for the dynamically decoupled controlled-Z gate operation to an integer number of Rabi oscillation periods.

18. The method of any one of clauses 11 to 17, wherein: the first qubit and the second qubit are both fluxonium qubits.

19. A non-transitory computer-readable medium comprising instructions that, when processed by a quantum computing system, cause the quantum computing system to perform first operations for implementing a dynamically decoupled controlled-Z gate operation, the first operations comprising: providing, by a first drive source to a second qubit of a superconducting circuit, an external magnetic flux to tune a frequency of the second qubit to a frequency of a first qubit, the first qubit being transversely coupled to the second qubit; providing, by a second drive source to the second qubit, a continuous alternating drive, a duration of the continuous alternating drive: based inversely on a magnitude of the continuous alternating drive; and within 10% of a quotient of pi divided by the magnitude of the continuous alternating drive; and reading out, after providing the second drive source, a state of the quantum computing system.

20. The non-transitory computer-readable medium of clause 19, wherein: the magnitude of the continuous alternating drive is selected to correspond to a first peak in a relationship between the magnitude and a fidelity of the dynamically decoupled controlled-Z gate operation.

21. The non-transitory computer-readable medium of any one of clauses 19 to 20, wherein: the duration and the magnitude of the continuous alternating drive is selected to synchronize a gate time of the dynamically decoupled controlled-Z gate operation to an integer number of Rabi oscillation periods.

22. The non-transitory computer-readable medium of any one of clauses 19 to 21, wherein: the first qubit and the second qubit are both fluxonium qubits.

In the drawings and specification, there have been disclosed exemplary embodiments. However, many variations and modifications can be made to these embodiments. Accordingly, although specific terms are employed, they are used in a generic and descriptive sense only and not for purposes of limitation or restriction of the scope of the embodiments, the scope being defined by the following claims.

What is claimed is:

1. A quantum computing system for performing a dynamically decoupled controlled-Z gate operation, comprising:
a superconducting circuit comprising:
a first qubit;
a second qubit transversely coupled to the first qubit; and
at least one computing device configured to:
provide, to a first drive source, first instructions causing the first drive source to apply an external magnetic flux to the second qubit to bring a frequency of the second qubit into resonance with a frequency of the first qubit; and
provide, to a second drive source, second instructions causing the second drive source to apply a continuous alternating drive with continuous phase to the second qubit.

2. The quantum computing system of claim 1, wherein:
a duration and a magnitude of the continuous alternating drive is configured to synchronize a gate time of the dynamically decoupled controlled-Z gate operation to an integer number of Rabi oscillation periods

3. The quantum computing system of claim 1, wherein:
a magnitude of the continuous alternating drive is selected based on a magnitude of an interaction term between the first qubit and the second qubit in a Hamiltonian of the superconducting circuit, the Hamiltonian specified for a frame rotating with the first and second qubits.

4. The quantum computing system of claim 3, wherein:
the magnitude of the continuous alternating drive is between one and three times the magnitude of the interaction term.

5. The quantum computing system of claim 1, wherein:
a duration of the continuous alternating drive is inversely based on a magnitude of the continuous alternating drive.

6. The quantum computing system of claim 1, wherein:
a duration of the continuous alternating drive is selected to be within 10% of a quotient of pi divided by a magnitude of the continuous alternating drive.

7. The quantum computing system of claim 1, wherein:
a magnitude of the continuous alternating drive is selected to correspond to a peak in a relationship between the magnitude and a fidelity of the dynamically decoupled controlled-Z gate operation.

8. The quantum computing system of claim 7, wherein:
the peak comprises a first peak in the relationship.

9. The quantum computing system of claim 1, wherein:
the first qubit and the second qubit are both fluxonium qubits.

10. The quantum computing system of claim 1, wherein:
the at least one computing device is further configured to provide, after providing the second instructions to the second drive source, third instructions to read out a state of the quantum computing system.

11. A method for performing a dynamically decoupled controlled-Z gate operation, comprising:
providing, by a first drive source to a second qubit of a superconducting circuit of a quantum computing system, an external magnetic flux to tune a frequency of the second qubit to a frequency of a first qubit, the first qubit being transversely coupled to the second qubit;
providing, by a second drive source to the second qubit, a continuous alternating drive, a magnitude of the continuous alternating drive corresponding to a peak in a relationship between the magnitude and a fidelity of the dynamically decoupled controlled-Z gate operation; and
reading out, after providing the second drive source, a state of the quantum computing system.

12. The method of claim 11, wherein:
the magnitude of the continuous alternating drive is selected based on a magnitude of an interaction term between the first qubit and the second qubit in a Hamiltonian of the superconducting circuit, the Hamiltonian specified for a frame rotating with the first and second qubits.

13. The method of claim 12, wherein:
the magnitude of the continuous alternating drive is between one and three times the magnitude of the interaction term.

14. The method of claim 11, wherein:
a duration of the continuous alternating drive is based inversely on the magnitude of the continuous alternating drive.

15. The method of claim 11, wherein:
a duration of the continuous alternating drive is selected to be within 10% of a quotient of pi divided by the magnitude of the continuous alternating drive.

16. The method of claim 11, wherein:
the peak comprises a first peak in the relationship.

17. The method of claim 11, wherein:
a duration and the magnitude of the continuous alternating drive are selected to synchronize a gate time for the dynamically decoupled controlled-Z gate operation to an integer number of Rabi oscillation periods.

18. The method of claim 11, wherein:
the first qubit and the second qubit are both fluxonium qubits.

19. A non-transitory computer-readable medium comprising instructions that, when processed by a quantum computing system, cause the quantum computing system to perform first operations for implementing a dynamically decoupled controlled-Z gate operation, the first operations comprising:
providing, by a first drive source to a second qubit of a superconducting circuit, an external magnetic flux to tune a frequency of the second qubit to a frequency of a first qubit, the first qubit being transversely coupled to the second qubit;
providing, by a second drive source to the second qubit, a continuous alternating drive, a duration of the continuous alternating drive:
based inversely on a magnitude of the continuous alternating drive; and
within 10% of a quotient of pi divided by the magnitude of the continuous alternating drive; and
reading out, after providing the second drive source, a state of the quantum computing system.

20. The non-transitory computer-readable medium of claim 19, wherein:
the magnitude of the continuous alternating drive is selected to correspond to a first peak in a relationship between the magnitude and a fidelity of the dynamically decoupled controlled-Z gate operation.

21. The non-transitory computer-readable medium of claim 19, wherein:
the duration and the magnitude of the continuous alternating drive is selected to synchronize a gate time of the dynamically decoupled controlled-Z gate operation to an integer number of Rabi oscillation periods.

22. The non-transitory computer-readable medium of claim 19, wherein:
the first qubit and the second qubit are both fluxonium qubits.
